(19) United States
(12) Patent Application Publication
(10) Pub. No.: US 2020/0166545 A1
(43) Pub. Date: May 28, 2020

(54) COAXIAL RESISTOR

(71) Applicant: ISABELLENHUETTE HEUSLER GMBH & CO. KG, Dillenburg (DE)

(72) Inventor: Ullrich HETZLER, Dillenburg-Oberscheld (DE)

(21) Appl. No.: 16/629,481

(22) PCT Filed: Jun. 22, 2018
(86) PCT No.: PCT/EP2018/066706

§ 371 Date: Jan. 8, 2020

(30) Foreign Application Priority Data
Jul. 12, 2017 (DE) 10 2017 115 649.6

(51) Int. Cl. G01R 1/20; H01C 1/148; H01C 1/144

(52) U.S. Cl. CPC G01R 1/203; H01C 1/144; H01C 1/148

(57) ABSTRACT

The invention concerns a coaxial resistor (1) having a forward conductor (6) and a return conductor (7) for conducting the current to be measured in opposite directions and having a resistor element made of a resistance material, the resistor element being arranged in the forward conductor (6) or in the return conductor (7) so that the current flows through the resistor element. The invention provides that the cross-section of at least the internal return conductor (7) is rectangular to the direction of current flow, which simplifies the manufacture of the coaxial resistor (1). Errors caused by thermoelectric voltages, TC of the resistor element and inhomogeneous current distribution are eliminated due to the design.

The invention concerns a coaxial resistor for measuring an electric current.

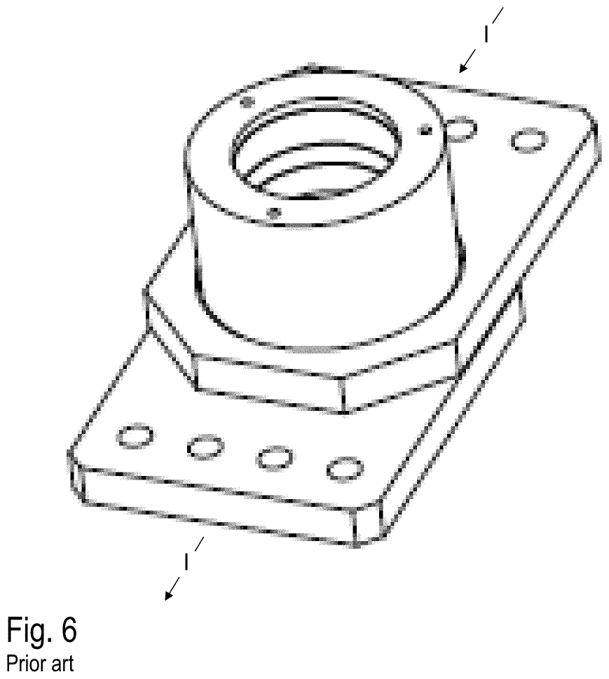

Such a coaxial resistor is known from WO 2007/068409 A1 (DE 10 2005 059 561 A1) and shown in FIG. 6. The electric current to be measured is supplied via a tubular conductor and then flows back in the opposite direction through a return conductor which is also tubular and arranged coaxially to the conductor. The advantage of this current flow in opposite directions is the fact that the magnetic fields generated by the electric current largely cancel each other out in certain areas inside. Here, the cross-section of the forward and return conductors is circular, which, however, with extremely low resistance values of a few μOhm, is associated with a relatively high manufacturing effort, primarily due to the difficult voltage connections to mount and the associated additional sources of error.

For the technical background of the invention, reference is made to DE 10 2014 011 593 B4.

The invention is therefore based on the task of creating a correspondingly improved coaxial resistor.

This task is solved by a coaxial resistor according to the invention according to the main claim.

The invention provides for the coaxial resistor to have an angular cross-section at least in the case of the internal return conductor, which considerably simplifies production because the return conductor can then be composed of angular plates.

In accordance with the known coaxial resistor, the coaxial resistor according to the invention first has a forward conductor and a return conductor for conducting the electric current to be measured, whereby the forward conductor and the return conductor are arranged coaxially and electrically connected in series, so that the current flows in the forward conductor and in the return conductor in opposite current flow directions. This current flow in opposite directions is advantageous—as already mentioned at the beginning with regard to the state of the art—because the magnetic fields generated by the electric current in the forward and return conductors are largely cancelled out in the area of the actual resistor element (see below).

In addition, the coaxial resistor according to the invention comprises, in accordance with the known coaxial resistor, a resistor element made of a resistance material (e.g. copper-manganese-nickel alloy), whereby the resistor element is arranged in the forward conductor or in the return conductor, so that the current flows through the resistor element. The electric voltage falling across the resistor element is proportional to the electric current in accordance with Ohm's law and is therefore a measure of the electric current to be measured. This enables a current measurement according to the four-wire technique, which is also known from EP 0 605 800 A1, for example.

The coaxial resistor according to the invention now differs from the known coaxial resistor described above in that the cross-section of at least the internal return conductor in a section plane rectangular to the direction of current flow is angular, in particular rectangular. In a preferred embodiment of the invention, the cross-section of the return conductor is square, but the cross-section can also have other rectangular shapes. In addition, the invention also offers the possibility that the cross-section of the return conductor may be triangular, pentagonal or generally polygonal. As mentioned briefly above, the angular cross-section offers the advantage that the return conductor can be composed of several flat plates, which considerably simplifies the production of the coaxial resistor according to the invention.

With the coaxial resistor according to the invention, the return conductor and optionally also the forward conductor consists of several flat, preferably rectangular plates, which can be assembled to form the forward conductor or the return conductor.

In a preferred embodiment of the invention, both the forward conductor and the return conductor are composed of rectangular plates. Here, it is preferable to have one plate of the forward conductor parallel to one plate of the return conductor. In this embodiment, both the return conductor and the forward conductor have an angular cross-section.

Alternatively, however, it is also possible that only the inner return conductor has an angular cross-section, while the outer forward conductor can have a round cross-section. For example, the outer forward conductor may have a circular cross-section and thus be tubular. In this case, the external forward conductor is thus conventionally designed as a tube, while the internal return conductor consists of several plates to simplify the manufacturing process.

The above-mentioned resistor element can be arranged either in the outer forward conductor or in the inner return conductor. The only decisive factor is that the electric current to be measured flows through the resistor element, so that the voltage drop across the resistor element forms a measure of the electric current to be measured in accordance with Ohm's law.

In the preferred embodiment of the invention, however, the resistor element is arranged in the internal return conductor. This is advantageous because the voltage measurement at the resistor element in the magnetic field-free space is simplified by a measuring circuit located within the coaxial resistor, as is still described in detailed form.

In the preferred embodiment of the invention, the two connection parts for the current supply and current removal as well as the forward and return conductors are made of massive copper plates in order to minimize the unavoidable power loss in the supply lines at high currents.

In the preferred embodiment of the invention, the resistor element is always arranged in an insert, whereby the insert is inserted in the forward conductor or return conductor and bridges a gap in the forward conductor or return conductor that runs transversely to the direction of current flow. The electric current to be measured thus flows through the insert which contains the resistor element, whereby the gap in the forward or return conductor running transversely to the direction of current flow prevents an undesired shunt connection past the insert.

The insert with the resistor element preferably consists of a composite material plate with two plate-shaped conductor elements made of a conductor material (e.g. copper) and the plate-shaped resistor element made of the resistor material (e.g. copper-manganese nickel alloy) lying between them in the direction of current flow. Such composite material plates are known for example from EP 0 605 800 A1 and can be produced cost-effectively from a composite material strip.

In addition, the coaxial resistor according to the invention preferably comprises plate-shaped connection parts made of a conductor material (e.g. copper) for the supply or discharge of the electric current to be measured, whereby the forward conductor and return conductor are each connected to one of the two connection parts.

The electric connection between the forward conductor and the return conductor on the one hand and the connection parts on the other hand can be made, for example, by soldering (e.g. brazing) or welding. In addition, forward and return conductors as well as the inserts can also be connected to each other by soldering (e.g. brazing) or welding in order to achieve the desired series connection of forward and return conductor.

It has already been briefly mentioned above that the two connection parts for current supply and current dissipation consist of flat, preferably rectangular plates. In addition, it should be noted that these plate-shaped connection parts are preferably aligned at right angles to the forward conductor and the return conductor. In addition, it should be noted that the plate-shaped connection parts for the power supply or current discharge are preferably arranged parallel to each other. The outgoing and return conductors can thus be placed on the plate-shaped connection parts.

It has already been mentioned above that the voltage drop across the resistor element is a measure of the electric current to be measured according to Ohm's law. One voltage tap preferably contacts the voltage-side conductor element of the insert, while the other voltage tap of the pair contacts the ground-side conductor element of the insert.

In the preferred embodiment, however, not only a single pair of voltage taps is provided, but several pairs of voltage taps are arranged spatially distributed. Each pair of voltage taps thus supplies a voltage measured value, whereby an average value can then be calculated from the various voltage measured values. In this way, inhomogeneities of the current distribution in the coaxial resistor can be taken into account. Basically, this principle of voltage measurement at various points is known from DE 10 2013 005 939 A1, so that the content of this patent application is fully attributable to the present description.

The voltage taps can have at least two contacts made of a conductor material (i.e. double taps) on the voltage side or ground side in order to achieve good thermal contact with a printed circuit board. This is advantageous for the compensation of unwanted thermoelectric voltages.

The connection between the voltage taps on the one hand and the conductor elements of the composite material plates (inserts) on the other hand can, for example, be made by soldering (e.g. brazing), welding or sintering.

It should also be mentioned that the voltage taps can be made of copper or the same composite material as the insert, in particular the same batch.

In order to form the voltage-side taps or the mass-side voltage taps, the invention may include a punched part which is connected to the voltage-side or mass-side conductor element of the insert (composite material plate).

For electric connection to a printed circuit board, the punched parts may have contact lugs, which may also be bendable. In the preferred embodiment, it is advantageous if in one pair of voltage taps made of one conductor material a narrow and possibly also thinner contact lug made of composite material is arranged on the ground side centrally between two contact lugs on the voltage side. This has the advantage that the temperature of the high side (voltage side) is effectively transferred to the printed circuit board via good thermal conduction due to the significantly larger cross-section of the contact lugs (double, thicker, wider and better thermal conductivity), so that the temperature at the solder joints of the printed circuit board is the same as the temperature at the voltage-side solder joint of the insert. Thus, the full temperature difference of the shunt is applied over the composite material vane, so that the temperature voltage compensation can function correctly.

The punched parts are electrically and mechanically connected to the conductor elements of the inserts (composite material plates). For example, this can be a sintered connection, a soldered connection (e.g. brazed connection) or a welded connection. In the case of a sintered joint, for example, this can be achieved by means of a silver sinter paste, which is previously printed and dried in a structured manner on the copper conductor elements. The sintered layer can, for example, consist of pure silver and be between 30 μm and 70 μm thick, depending on the printing density of the sinter paste.

In a preferred embodiment of the invention, the punched parts are approximately 0.3 mm thick, but other thicknesses of the punched parts are also possible within the scope of the invention.

It should also be mentioned here that at least one (e.g. the mass-produced) punched part and the associated composite material plates (inserts) preferably consist of the same composite material, in particular the same batch of a composite material strip. This is advantageous for compensating thermoelectric voltages.

It has already been briefly mentioned above that the electric voltage falling across the resistor element forms a measure of the electric current to be measured in accordance with Ohm's law. To measure this voltage drop, a measuring circuit is preferably provided which can be arranged inside the return conductor. This measuring circuit is preferably located on a printed circuit board which is connected to the contact lugs of the punched parts, whereby the printed circuit board is preferably arranged transversely, in particular at right angles, to the current flow direction in the forward conductor and the return conductor. At its front edges, this printed circuit board preferably has terminals (e.g. solder pads) for connection to the voltage taps in order to measure the voltage drop across the resistor element. The connection between the voltage taps on the one hand and the printed circuit board on the other hand can be made using the contact lugs of the punched parts mentioned above.

The outer cross-section of the printed circuit board is preferably matched to the inner cross-section of the inner return conductor, so that the printed circuit board fills the free inner cross-section of the inner return conductor up to a circumferential gap. The contact lugs of the punched parts mentioned above can then bridge the circumferential gap between the printed circuit board and the return conductor and contact the printed circuit board. If the internal return conductor has a square cross-section, the printed circuit board is also preferably square. In the case of a triangular cross-section of the internal return conductor, the printed circuit board is also preferably triangular. Each plate of the return conductor is therefore preferably assigned a front edge of the printed circuit board so that the printed circuit board can easily contact all inserts in the plates of the return conductors.

The printed circuit board preferably has several printed circuit board levels and is therefore multi-layer. Balancing resistors may be located in a first printed circuit board level (e.g. on the upper side), whereby the balancing resistors are each assigned with individual pairs of voltage taps in order to weight the individual voltage measured values, as is known, for example, from DE 10 2013 005 939 A1.

In addition, the first printed circuit board level can also contain a resistor to compensate for the temperature dependence of the resistor element and/or a temperature sensor.

A second printed circuit board level contains a resistor made of copper, which is also used for temperature compensation. This can also consist, for example, of two resistors connected in parallel, which allow the two measuring voltages from the double taps to be averaged. In addition, the circuit board can also have a third and a fourth printed circuit board level. For example, copper connection surfaces for heat compensation can be located on the underside of the printed circuit board in the area of the copper resistors.

For example, the compensation of thermoelectric voltages is known from DE 10 2016 008 415.4, so that the content of this earlier patent application is also fully incorporated into this description.

It should also be mentioned that the coaxial resistor according to the invention preferably has a relatively high continuous current carrying capacity, which can be at least 1 kA, 2 kA, 3 kA, 4 kA or even 5 kA.

The preferred conductor material is copper or a copper alloy. Alternatively, it is also possible that the conductor material is aluminium or an aluminium alloy.

It should also be mentioned that the conductor material preferably has a higher specific electrical conductivity than the resistance material.

For example, a copper-manganese-nickel alloy such as Cu82Mn12Ni4 (Manganin®) can be used as the resistance material within the scope of the invention. Alternatively, it is also possible to use a nickel-chromium alloy or another resistance alloy as the resistance material.

However, the resistance material of the resistor element preferably has a specific electrical resistance in the range 1·10⁻⁸ Ωm to 50·10⁻⁷ Ωm

The resistance value of the total coaxial resistor, on the other hand, is preferably in the range from 0.1 μΩ to 1 mΩ.

It should also be mentioned that the resistance value of the coaxial resistor is preferably very temperature constant with a temperature coefficient of less than 500 ppm/K, 200 ppm/K or even 50 ppm/K.

Other advantageous modifications of the invention are indicated in the dependent claims or explained in more detail below together with the description of the preferred embodiments of the invention using the figures. They show:

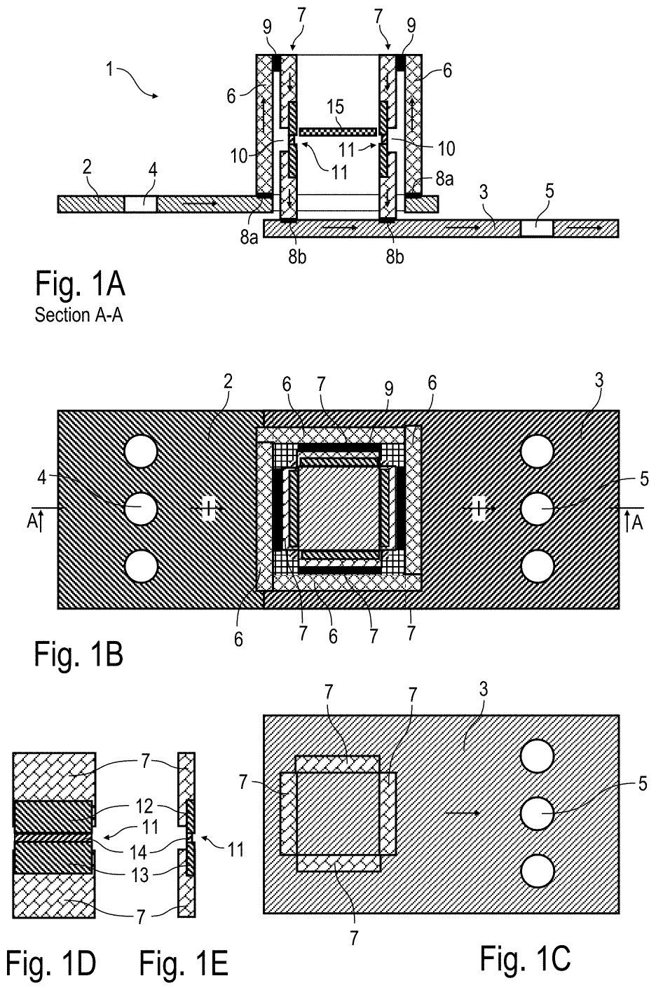

FIG. 1A a cross-sectional view through an coaxial resistor according to the invention along the section line A-A in FIG. 1B,

FIG. 1B a view of the coaxial resistor according to FIG. 1A,

FIG. 1C shows a part of the coaxial resistor according to the invention with a connection part and attached plates of the return conductor,

FIG. 1D a view of a plate-shaped return conductor with an inserted insert,

FIG. 1E a cross-sectional view through the return conductor with the insert as shown in FIG. 1D,

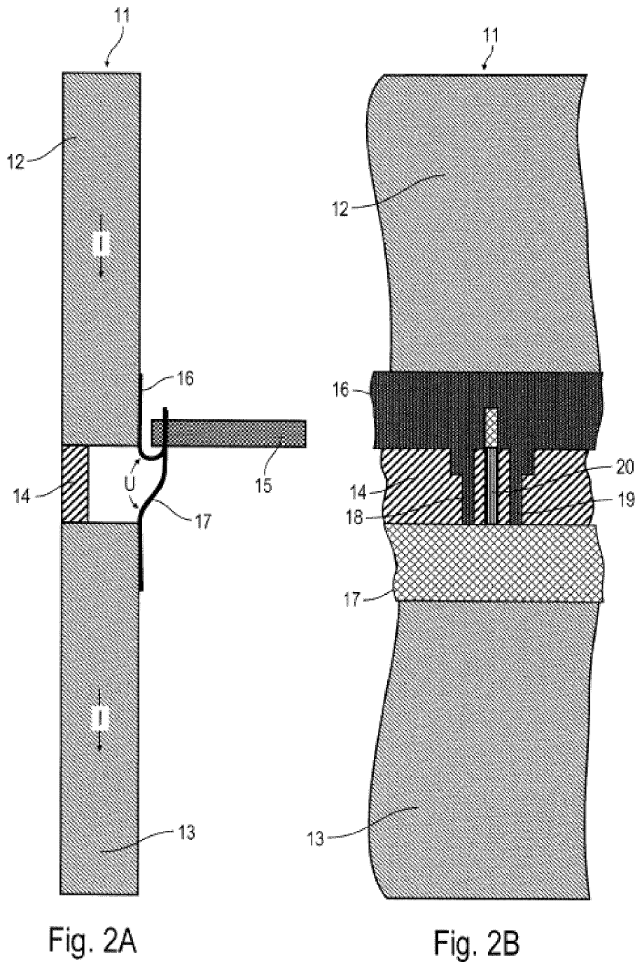

FIG. 2A a simplified cross-sectional view through the insert with the punched parts for contacting and a printed circuit board,

FIG. 2B a view of the arrangement according to FIG. 2A,

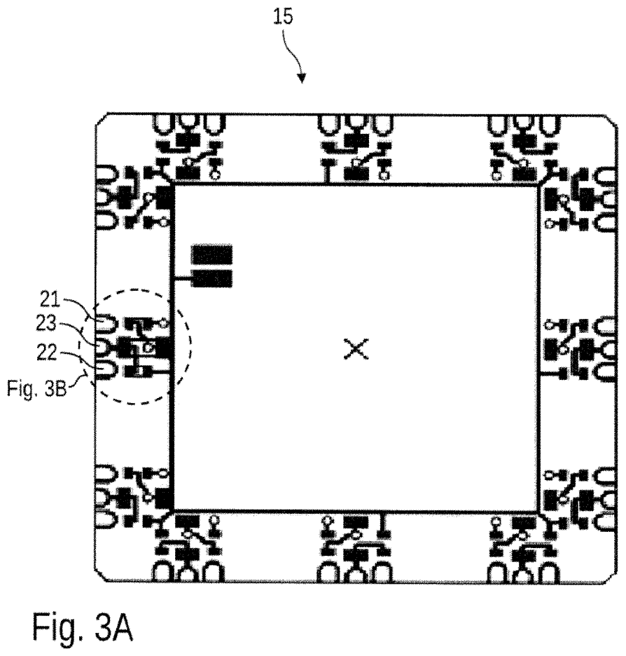

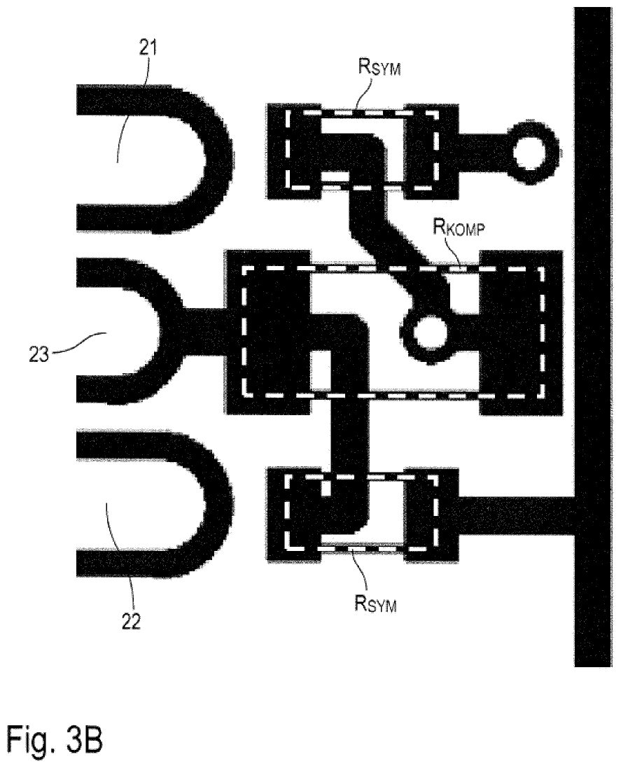

FIG. 3A a view of the printed circuit board for the measurement circuit with twelve pairs of voltage taps,

FIG. 3B an enlarged detailed view of a pair of tension taps from FIG. 3A,

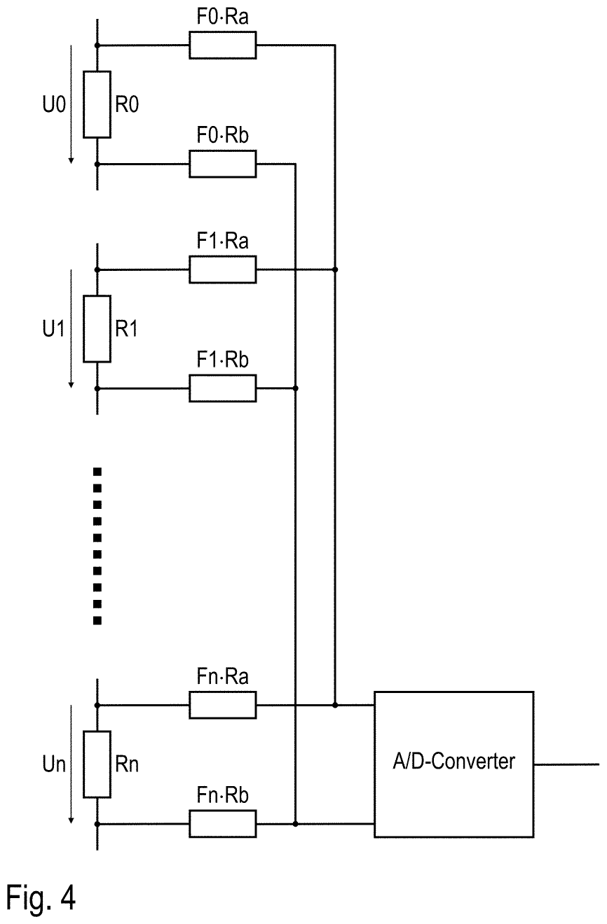

FIG. 4 shows a schematic diagram explaining the weighting of the voltage measured values of the individual pairs of voltage taps,

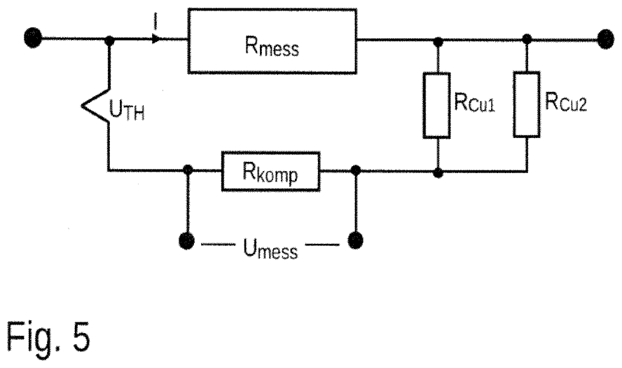

FIG. 5 a simplified circuit diagram explaining the compensation of thermal stresses and the compensation of the TC of the resistor element, and

FIG. 6 a perspective view of a conventional coaxial resistor according to the state of the art.

The drawings show a coaxial resistor 1 according to the invention for the measurement of an electric current I according to the known four-wire technique.

The electric current I to be measured is introduced into the coaxial resistor 1 via a plate-shaped connection part 2 made of a conductor material (e.g. copper) and is led out again from the coaxial resistor 1 via a plate-shaped connection part 3 made of the same conductor material.

The two connection parts 2 and 3 each have holes 4 and 5 for the passage of screws, so that the two connection parts 2 and 3 can, for example, be screwed together with current bars.

The electric current I to be measured flows in the direction of the arrows from the connection part 2 first through a forward conductor 6 and then in the opposite direction through a return conductor 7 to the connection part 3. The forward conductor 6 and the return conductor 7 each consist of a conductor material (e.g. copper) and guide the electric current Ito be measured in opposite directions. This is advantageous because the magnetic fields generated by the electric current I in the forward conductor 6 on the one hand and in the return conductor 7 on the other hand cancel each other out on the inside.

The forward conductor 6 consists of four rectangular plates which are aligned at right angles to the connection part 2 and placed on the upper side of the connection part 2. The rectangular plates of the forward conductor 6 and the return conductor 7 are connected to the upper side of the connection part 2 or the connection part 3 by brazing connections 8a or 8b.

On their upper side, the rectangular plates of the forward conductor 6 are also connected to the rectangular plates of the return conductor 7 by a brazing connection 9.

It should be noted that the rectangular plates of the return conductor 7 are divided in two and divided by a gap 10, the gap 10 preventing a current flow between the two adjacent parts of the return conductor 7.

The gap 10 is bridged by inserts 11, each of which is inserted into a shoulder in the adjacent plates of the return conductor 7 and connected to it.

The inserts 11 are shown in detail in FIGS. 1D and 1E and consist of two plate-shaped conductor elements 12, 13 made of a conductor material (e.g. copper) and a resistor element 14 made of a resistance material (e.g. Manganin®) in between. The inserts 12, 13 can, for example, be manufactured from a composite material strip, as is known from EP 0 605 800 A1, for example. The electric current Ito be measured therefore flows through the inserts 11 and thus also through the resistor element 14 when it flows through the return conductor. The voltage drop U (see FIG. 2A) over the resistor element 14 of the inserts 11 thus forms a measure of the electric current to be measured according to Ohm's law. This voltage drop is measured via a measuring circuit arranged on a printed circuit board 15, whereby the printed circuit board 15 is arranged inside the return conductor 7 and aligned at right angles to the direction of current flow.

Due to the expected inhomogeneity of the current distribution within the resistor, a large number of pairs of voltage taps are formed whose measured values are averaged in a suitable manner.

In a simplified version for lower currents or higher resistance values, the insert can form the complete return conductor including the return conductor 7.

Two punched parts 16, 17 are provided for the electric connection of the printed circuit board 15 with the two plate-shaped connection parts 12, 13 of the insert 11, as can be seen in particular from FIGS. 2A and 2B.

The two punched parts 16, 17 are preferably connected by a sintered connection to the two plate-shaped connection parts 12 and 13 of the inserts 11. For this purpose, a silver sinter paste is first printed onto the conductor elements 12 and 13 and dried. The punched parts 16, 17 are then applied precisely in a low-temperature sintering process (250°−260° C.). The sintered connecting layer consists of pure silver and is between 30 μm and 70 μm thick, depending on the pressure density of the sinter paste. This connection between the punched parts 16, 17 on the one hand and the conductor elements 12, 13 on the other hand also survives the subsequent brazing process undamaged, in which the entire coaxial resistor 1 is brazed. The connection becomes even more stable through intensive diffusion of copper and silver. However, the joint can also be made as a welded or brazed joint.

The voltage-side punched part 16 has two adjacent contact lugs 18, 19, whereby a contact lug 20 is formed on the ground-side punched part 17, which runs centrally between the two contact lugs 18, 19 of the voltage-side punched part 16. The contact lugs 18-20 are bent accordingly to contact the printed circuit board 15, as shown in FIG. 2A. During assembly, the printed circuit board 15 rests on the shoulders of the curved contact lugs 18-20 as a positioning aid. The contact lugs 18, 19 together form a voltage tap on the high side (voltage tap), while the contact lug 20 forms a voltage tap on the low side (ground side).

The large number of solder connections between the printed circuit board 15 and the inserts 11 guarantees good strength for the connection between the printed circuit board 15 and the coaxial resistor 1, whereby the curved contact lugs 18-20 allow a certain mechanical compensation in the event of possible tensions due to temperature changes.

The double contact lugs 18, 19 on the voltage side (high-side) offer the advantage that the temperature of the voltage side is effectively transferred to the printed circuit board 15 by the good thermal conduction via the contact lugs 18, 19 (double, short length, wide contacts and very high thermal conductivity). Thus, the full temperature difference of the shunt is applied over the composite material terminal 20, so that the thermoelectric voltage compensation can function correctly.

The punched part 17 on the ground side consists of the same composite material strip as the insert 11 in order to be able to compensate the unavoidable thermoelectric voltages in the insert as optimally as possible. Preferably, the mass-produced punched part 17 even consists of the same batch of the same composite material strip.

FIGS. 3A and 3B show details of the printed circuit board 15. FIG. 3a shows that in the realized case three pairs of voltage taps per insert 11 are formed. FIG. 3B shows that for each pair of voltage taps, the printed circuit board 15 has two connection pads 21, 22 for the contact lugs 18, 19 and a central connection pad 23 for the contact lug 20.

It should also be mentioned that the printed circuit board is 15 multilayer and has R_{SYM} symmetry resistors on its top side, whereby the R_{SYM} symmetry resistors have the task of weighting the voltage measured values of the individual pairs of voltage taps, as is known for example from DE 10 2013 005 939 A1.

In addition, the top side of the printed circuit board 15 also carries a compensating resistor R_{KOMP} to compensate for the temperature dependence of the resistor element, as is known from DE 10 2016 008 415.4, for example.

FIG. 4 shows a simplified equivalent circuit diagram to illustrate the weighting of the individual voltage measured values of the individual pairs of voltage taps. The resistors R0, R1, . . . , Rn are the resistor elements 14 in the individual inserts 11. The resistors Ra, Rb correspond to the balancing resistors R_{SYM} in FIG. 3B. The functionality of this circuit is described for example in DE 10 2013 005 939 A1, so that reference is made to this earlier patent application.

Finally, FIG. 5 shows an equivalent circuit diagram to illustrate the compensation of thermal voltages Uₜₕ by the composite material flag 20. The function of this compensation of thermal voltages is described, for example, in DE 10 2016 008 415.4, so that reference can also be made to this earlier patent application.

The drawing also shows two copper resistors R_{CU1} and R_{CU2} connected in parallel, which are arranged in a second plane of the printed circuit board 15 and emanate from copper terminals on the voltage side and serve as temperature sensors for TC compensation. In addition, the two resistors R_{CU1} and R_{CU2} calculate the mean value of the two potential values on the voltage side.

The invention is not limited to the preferred embodiments described above. Rather, a large number of variants and modifications are possible which also make use of the idea according tot he invention and therefore fall within the scope of protection. In particular, the invention also claims protection for the subject-matter and the characteristics of the dependent claims independently of the claims referred to in each case. The invention thus comprises various invention aspects which enjoy protection independently of each other.

### LIST OF REFERENCE SIGNS

1 Coaxial resistor
2 Plate-shaped connection part for current supply
3 Plate-shaped connection part for current dissipation
4 Hole in the connection part for tightening a connection contact
5 Hole in the connection part for tightening a connection contact
6 Forward conductor
7 Return conductor
8a Brazing connection between the forward conductor and the plate-shaped connection part
8b Brazing connection between return conductor and plate-shaped connection piece
9 Brazing connection between the forward conductor and the return conductor
10 Gap in the return conductor
11 Composite insert in the return conductor
12, 13 Plate-shaped conductor elements of the insert
14 Plate-shaped resistor element of the insert
15 Printed circuit board
16 Voltage-side punched part for voltage tapping
17 Mass-side punched part for voltage tapping
18, 19 Contact lugs of the voltage-side punched part for contacting the printed circuit board
20 Contact lug of the punched part on the ground side for contacting the printed circuit board
21, 22 Connection pads in the printed circuit board for the voltage-side contact vanes
23 Connection pads in the printed circuit board for the ground-side contact lug
I Electric current through the coaxial resistor
Ra, Rb Balancing resistors in the printed circuit board
R_{CU1}, R_{CU2} Resistors for compensation of temperature dependence
R_{KOMP} Compensating resistor on the printed circuit board
R0, . . . , Rn Resistor elements
R_{MESS} Resistor element
R_{SYM} Balancing resistors on the printed circuit board
U Voltage drop across the resistor element
U_{TH} Thermoelectric voltage in the mass-side punched part made of composite material
U1, . . . , Un Voltage drop across resistor elements R0, . . . , Rn

1-16. (canceled)

17. Coaxial resistor for measuring an electric current, comprising
a) a forward conductor for conducting the current to be measured,
b) a return conductor located inside the forward conductor for conducting the current to be measured, the forward conductor and the return conductor being arranged coaxially and electrically connected in series and conducting the current in opposite current flow directions, and having
c) a resistor element made of a resistance material, the resistor element being arranged in the forward conductor or in the return conductor so that the current flows through the resistor element,
d) wherein the cross-section of at least the internal return conductor in a section plane perpendicular to the current flow direction is angular.

18. Coaxial resistor according to claim 17, wherein the internal return conductor consists of a plurality of flat, rectangular plates.

19. Coaxial resistor according to claim 18, wherein the external forward conductor consists of a plurality of flat, rectangular plates.

20. Coaxial resistor according to claim 19, wherein the plates of the forward conductor on the one hand and the plates of the return conductor on the other hand are each arranged in pairs parallel to one another.

21. Coaxial resistor according to claim 17, wherein the outer forward conductor has a round cross-section.

22. Coaxial resistor according to claim 19, wherein
a) the plates of the return conductor contain the resistor element and
b) the resistor element is in each case contained in an insert which is inserted in the return conductor and bridges a gap in the return conductor, which runs transversely to the current flow direction, and
c) the inserts each consist of a composite material plate comprising two plate-shaped conductor elements of a conductor material and the plate-shaped resistor element lying between them in the current flow direction.

23. Coaxial resistor according to claim 17, further comprising
a) a first connection part made of a conductor material for supplying the current to the coaxial resistor,
b) a second connection part made of a conductor material for removing the current from the coaxial resistor,
c) the forward conductor and the return conductor each being electrically and mechanically connected to one of the two connection parts.

24. Coaxial resistor according to claim 23, wherein
a) the electric connection between the forward conductor and the return conductor on the one hand and the connection parts on the other hand is at least one of a soldered connection and a welded connection, and
b) the electric connection between the forward conductor and the return conductor is at least one of a brazed joint and a welded joint.

25. Coaxial resistor according to claim 24, wherein
a) the two connection parts consist of flat, rectangular plates, and
b) the two plate-shaped connection parts are aligned at right angles to the plates of the forward conductor and of the return conductor.

26. Coaxial resistor according to claim 17, wherein at least one pair of voltage taps is provided in each case for measuring the electric voltages falling over the resistor elements.

27. Coaxial resistor according to claim 26, wherein a plurality of pairs of voltage taps are provided, the pairs of voltage taps being arranged at different voltage measuring points.

28. Coaxial resistor according to claim 27, wherein the voltage taps have at least two contacts as double taps on the voltage and ground side in order to achieve good heat transfer to a printed circuit board.

29. Coaxial resistor according to claim 28, wherein the voltage taps are connected to the conductor elements of the composite material plate of the insert by a joint selected from a group consisting of:
a) a soldered joint,
b) a welded joint, and
c) a sintered compound.

30. Coaxial resistor according to claim 29, wherein the voltage taps consist of copper.

31. Coaxial resistor according to claim 29, wherein the mass-side voltage taps consist of the same composite material as the composite material plate of the insert.

32. Coaxial resistor according to claim 30, wherein
a) a punched part is provided for forming the voltage-side voltage taps, which punched part is connected to the voltage-side plate-shaped conductor element of the insert, and
b) a punched part, which is connected to the plate-shaped conductor element of the insert on the mass-side, is provided in order to form the voltage taps on the mass-side.

33. Coaxial resistor according to claim 32, wherein
a) the punched parts have contact lugs for electric connection to a printed circuit board, and
b) in at least one pair of the voltage taps a ground-side contact lug is arranged centrally between two voltage-side contact lugs.

34. Coaxial resistor according to claim 33, wherein the punched parts are each connected to the plate-shaped conductor elements of the inserts by one of the following connections:
a) a sintered connection,
b) a soldered joint, and
c) a welded joint.

35. Coaxial resistor according to claim 34, wherein
a) the sintered connection is made by means of a silver sinter paste; and
b) the sintered connection comprises a sintered layer having a layer thickness of 30 μm to 70 μm.

36. Coaxial resistor according to claim 35, wherein
a) the punched parts have a thickness of more than 0.1 mm and less than 2 mm, and
b) one of the punched parts and the composite material plates of the insert consist of the same composite material.

37. Coaxial resistor according to claim 17, wherein
a) a measuring circuit is arranged on the inside between the forward conductor and the return conductor, which measuring circuit detects the voltage which drops over the resistor element,
b) the measuring circuit is arranged on a printed circuit board,
c) the printed circuit board is connected to the contact lugs of the punched parts,
d) the printed circuit board is arranged transversely to the current flow direction in the forward conductor and the return conductor,
e) the printed circuit board has terminals on at least one lateral end edge for connection to the voltage taps, and
f) the printed circuit board has terminals on all lateral end edges for connection to the voltage taps of the parallel inserts.

38. Coaxial resistor according to 37, wherein
a) a first printed circuit board plane contains balancing resistors, the balancing resistors each being assigned to the individual pairs of voltage taps in order to weight the individual voltage measured values,
b) the first printed circuit board plane contains a resistor for compensating the temperature dependence of the resistor element,
c) a second printed circuit board plane contains a resistor made of copper which serves as a temperature sensor for compensating the temperature dependence of the resistor element,
d) the copper resistor for temperature compensation consists of two resistors which are connected in parallel and form an average value of the two measuring voltages from the double tap, and
e) a third printed circuit board plane and a fourth printed circuit board plane have copper connection surfaces for heat compensation in the region of the copper resistors.

39. Coaxial resistor according to claim 17, wherein
a) the coaxial resistor has a continuous current carrying capability of at least 1 kA;
b) the conductor material is copper or copper alloy or aluminium or aluminium alloy;
c) the conductor material has a higher specific electric conductivity than the resistance material;
d) the resistance material is a copper-manganese alloy, or a nickel-chromium alloy;
e) the resistance material of the resistor element has a resistive electric resistance which is
e1) less than 50·10⁻⁷ Ωmm, and
e2) is greater than 1·10⁻⁸ Ωm;
f) the coaxial resistor has a resistance value which is
f1) at least 0.1 μΩ and
f2) a maximum of 1000 μΩ, and
g) the coaxial resistor has a resistance value with a temperature coefficient of less than 500 ppm/K.
